(19) United States
(12) Patent Application Publication
(10) Pub. No.: US 2007/0152696 A1
(43) Pub. Date: Jul. 5, 2007

(54) Water bond-out

(76) Inventors: Larry K. Ross, Los Gatos, CA (US); Richard A. Portune, Sunnyvale, CA (US)

Correspondence Address: Deborah Wenocur;c/o Shelly Garrett, Credence Systems Corporation, 1421 California Circle, Milpitas, CA, 95035, US

(21) Appl. No.: 11/385,420

(22) Filed: Mar. 21, 2006

Related U.S. Application Data
(60) Provisional application No. 60/755,827, filed on Jan. 3, 2006.

(51) Int. Cl. G01R 31/26

(52) U.S. Cl. 324/765

(57) ABSTRACT

A method for forming an improved electrical connection to a die or wafer which does not utilize micro-probes, is physically compatible with ultra-high NA objectives used for low photon emission observation, forms more secure electrical connections, is practical for contacting a die at any position on a full wafer. The method can be used for failure analysis utilizing electrical stimulation of the die yielding optical or thermal output. It can also be used in methods wherein optical stimulation yields electrical output.

### FIELD OF THE INVENTION

This invention relates to methods of applying electrical connections and/or conditioning to a silicon or silicon-like wafer for chip diagnostic purposes.

### BACKGROUND OF THE INVENTION

In the field of integrated circuit processing, not only have device critical dimensions been steadily decreasing and circuit complexity been steadily increasing, but the size of the wafers in which the devices and circuits are built has grown greatly. Whereas wafer dimensions were three to four inch radius twenty years ago, typical wafer radii at present are twelve inches or more. The increased circuit complexity and wafer size presents new challenges in chip diagnostics and testing.

One typical method of diagnosing design flaws and/or fabrication problems in a circuit, or providing electrical conditioning to the circuit, involves applying electrical signals such as Vdd, ground, or other signals so as to power up or “turn on” the circuit, and then to observe such effects as photon emission or thermal effects to locate potential trouble spots. In the past, observation was generally done on a die-by-die basis with a microscope from the front side of the die, i.e., through the metal layers. FIG. 1a illustrates a typical configuration: Die 100 has metal contact pads 105 on its frontside edges, to which external electrical connections 110 are contacted. Observation is done with microscope 115 positioned proximal frontside 120 of die 100.

Other diagnostic techniques used for the investigation of integrated circuit defects and sensitive areas utilize a laser beam incident on the DUT. When a laser beam impinges on a material such as a semiconductor substrate or metal interconnect, it can cause thermal effects and/or photo-generated charge carrier effects, both of which can be utilized to localize many types of circuit defects. TIVA (Thermally Induced Voltage Alteration) and OBIRCH (Optical Beam Induced Resistance Change) are two methods developed to utilize thermal effects for circuit defect analysis. LIVA (Light Induced Voltage Alteration) is a method developed to utilize photo-generated charge carrier effects for circuit defect analysis. All of these methods involve a laser stimulus of the DUT, and electrical or thermal measurements of the response to the stimulus. The TIVA method is described in U.S. Pat. No. 6,078,183, issued on Jun. 20, 2000, the LIVA method is described in U.S. Pat. No. 5,430,305 issued on Jul. 4, 1995, and the OBIRCH method is described in U.S. Pat. No. 5,804,980 issued on Sep. 8, 1998. These three patents are hereby incorporated by reference in their entireties. Other methods which use laser stimulation to produce perturbations of mechanical, thermal, or electrical properties of the die include but are not limited to: Optical Beam Induced Current (OBIC), Laser Assisted Device Alteration (LADA), Soft Defect Localization (SDL), Externally Induced Voltage Alteration (XIVA), and Resistive Interconnection Localization (RIL). A general description of many of these methods is found in Microelectronics Failure Analysis Desk Reference, 5^{th} Ed., ASM International, Materials Park, Ohio, 2004, Chapter 10, Laser and Particle Beam-Based Localization Techniques, pp 407-444.

Both the observation of photoemission or thermal response from the DUT resulting from electrical stimulation, and the electrical measurement of changes caused by optical stimulation, require reliable electrical connection to the sample.

Traditionally, the electrical connections have been provided by “micro-probes” which are mounted on supports and steered with mini-controls to contact the die in various locations such as the contact pads. FIG. 1b illustrates the structure of a standard probe station including microprobes and their controls. Wafer or DUT 135 is placed on tabletop 140 and generally held by vacuum suction. Platen 145 with hole 150 therethrough is positioned over die 155 being probed. Microprobe needle 160 is positioned on die 155 using probe support/micromanipulator 165, which is attached to platen 145. Voltage and current measurements are performed by the electrical measurement instruments 170 attached to the probe needle 160 through the micromanipulator. Common instruments attached to the probe station are voltmeters, curve tracers, oscilloscopes,and the like. Circuit excitation from voltage supplies, waveform generators, and the like may also be supplied to the die circuit in the same manner. When applicable, observation of the DUT may be done using microscope 180.

Microprobes have several disadvantages. They are expensive and easily damaged, and the connections made to the die are not permanent and not reliably good quality connections. In addition the microprobe supports are bulky, and it is physically difficult to fit more than 6-8 microprobes around the die. FIG. 1c shows the physical constraints on multiple microprobes.

Microprobes are also physically incompatible with the improved ultra-high NA objectives used for low emission observation, such as provided by the Credence 10-104001-00 lens set or 10-106015-00 lens set, unless observation is done from the die side opposite the micro-probes, i.e., the backside. Such objectives typically have bulky (large diameter) bodies and very small (2-10 mm) focal working distances that require the objective to be positioned very close to the DUT. The size and shape of microprobes renders the use of such objectives on the connection side, i.e. the frontside, of the DUT impossible. This is illustrated in FIG. 1d. Ultra-high NA objective lens 181 with wide profile physically interferes with microprobes 182 as it approaches the DUT surface. Whereas in many cases it is advantageous to observe emission from the die backside, there are times when frontside observation is preferable. FIG. 1e illustrates an integrated circuit die 183 with metal layers 184 shown. In this case, the emission location 185 is near frontside 190 of integrated circuit die 186, which would permit easy frontside emission detection by objective lens 191 via path 193, but for which backside emission detection would be difficult, since a circuitous path 195 would be required.

The recent trend in diagnostic testing is to test individual devices at the “whole wafer” level, rather than separating and testing individual dies. This has many advantages, including:
1) No costly die “fixturing” is necessary—“on-wafer” fixturing is more than 90% less expensive, due to the set-up for individual die testing as described below.
2) Set-up preparation for individual die testing may exceed 6 weeks.
   For individual die testing, a whole wafer must be sent to a dicing facility to separate individual dies. Dies must then be packaged for handling and sent to a packaging facility. Dies are then packaged individually, as if for sale to an end user. The resulting packaged parts must then be prepared for test and data collection, a process which involves careful deconstruction of the packaged part to expose the die contained within. Finally, a single-use DUT board with socket must be designed and produced to make electrical connection to the DUT possible. Frequently, many, if not all of these steps require outside vendors or departments within a facility to process the devices since such capabilities are seldom contained within the Failure Analysis lab environment.
   In contrast, set-up preparation time for “on-wafer” testing can be less than one hour.
3) Eliminates additional problems that may be created by handling the parts, e.g., “dicing” the wafer, and attaching the fixturing.

In addition to the disadvantages outlined above for the use of microprobes for on-wafer diagnostics, it is generally highly impractical to physically place more than 4 microprobes anywhere on a large wafer. This is because it is difficult for a microprobe to be positioned so as to reach across the radius of a wafer to make contact with a die. As a result, microprobes can only be placed on the side of the die of interest closest to the edge of the wafer. Generally no more than 4 microprobes can be fit on one side of the die. A loose die can be reached from both sides but then the physical bulk of the microprobe positioners limits the number of microprobes to 6-8.

A method for forming high-quality electrical connections to a die, whether in single-die or full-wafer environment, which avoided the disadvantages of microprobes and which could be used with the improved ultra-high NA objectives used for low photon emission observation, as well as for optically stimulated electrical measurements or other diagnostic methods, would be an important advancement in chip diagnostic technology.

### SUMMARY OF THE INVENTION

It is therefore an object of this invention to provide an improved form of electrical connection to a die or wafer which does not utilize micro-probes.

It is a further object of this invention to provide a form of electrical connection to a die or wafer which is physically compatible with ultra-high NA objectives used for low photon emission observation.

It is a further object of this invention to provide a form of electrical connection to a die or wafer which is practical for contacting a die at any position on a full wafer.

These objectives are met by the wafer bond-out scheme disclosed herein.

### BRIEF DESCRIPTION OF THE FIGURES

FIG. 1a illustrates a prior art configuration for chip diagnostics utilizing microprobes.

FIG. 1b illustrates the structure of microprobes and their controls.

FIG. 1c shows the physical constraints on multiple microprobes.

FIG. 1d shows the difficulty in using microprobes with ultra-high NA objectives.

FIG. 1e illustrates a case where frontside emission observation is preferable to backside observation.

FIG. 2 illustrates a configuration for performing permanent electrical/mechanical attachment to a die according to the present invention.

FIG. 3 illustrates wedge bonding.

FIG. 4a illustrates a configuration for on-wafer bond-out according to the present invention.

FIG. 4b illustrates a close-up of the DUT with a large number of micro-bonds, according to the present invention.

### DETAILED DESCRIPTION OF THE INVENTION

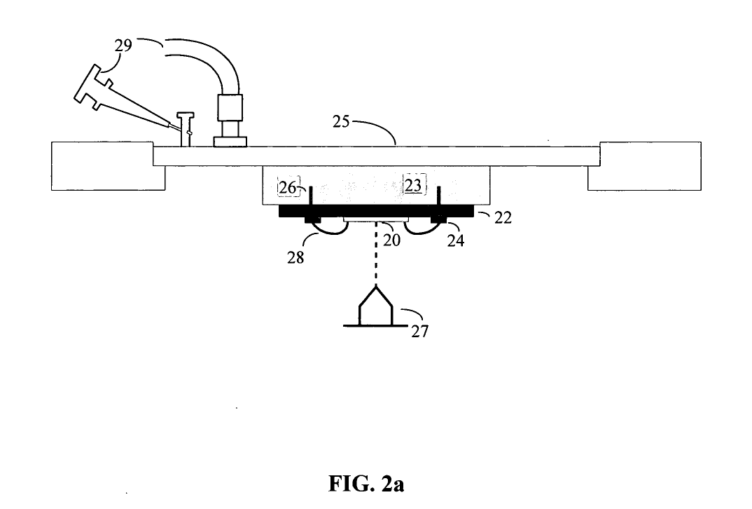

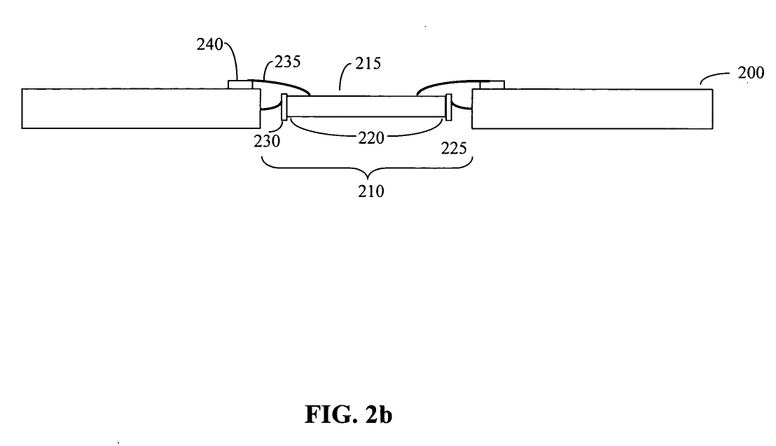

A method and configuration for performing permanent electrical/mechanical attachment to a die which does not utilize micro-probes, and which enables observation of photon emission from the die frontside without interfering with the microscope objective lens, even for ultra-high NA objectives, is shown in FIG. 2a. It will be apparent to those skilled in the art that types of observed response to the electrical stimulation of the DUT other than photon emission are also possible. By way of example, thermal responses to the electrical stimulation of the DUT may also be observed and measured.

Die (20) is glued (from the backside) to standardized device carrier, i.e. circuit board, (22). An adhesive which is soluble in a benign solvent such as isopropyl alcohol (IPA) or acetone is required. A low-viscosity, cyanoacrylate-based adhesive is preferably used, such as (LocTite type 460). The substrate and DUT must be cleaned using IPA or Acetone and allowed to dry thoroughly. A small amount of sample adhesive is applied to the substrate and the DUT is attached and clamped in place using finger-tip pressure for approximately 30 seconds. A device prepared in this fashion is ready for wire bonding in approximately 5 minutes. Note; the adhesive can be dissolved using acetone if desired to separate DUT and carrier for reclamation of either component. The carrier (22) is a low cost consumable, which may, by way of example, have 24 contact pads (24). Each contact pad (24) is connected to a pin (26) extending from the backside of the carrier. Then, die (20) is electrically/mechanically connected to carrier (22) by bonding micro-wires (28) to points on the die and connecting those micro-wires to contact pads (24). Any manual bonder capable of wedge-bonding with Al—Si wire is suitable for this process. One tool of choice is the F&K Delvotec model 5330. Other suitable tools include the Hybond model 572A and WestBond Model 7476E. Each die (20) is thereby custom-wired to inexpensive standardized carrier (22). The custom-wired carrier is then plugged into a standard socket 23 such as a Zero Insertion Force (ZIF) socket, which may be mounted on a standardized DUT card 25 The ZIF socket allows the prepared DUT to be easily replaced and reused with little or no damage or war to either the DUT or the DUT card. The DUT card may, for example, have each line include an available test point and SMA connector. Electrical connections 29 are on the side of the DUT card opposite the socket. Since the wiring from the die to the carrier is customized, only a single DUT card is required.

This direct bond-out configuration enables frontside observation by data optics 28 such as ultra-high NA objectives without any physical interference with the lens due to the low profile and small physical size of the wire bonds. It also provides permanent bonding onto an inexpensive carrier with good electrical/mechanical connection and fast, one-time set-up, on the order of 30 minutes, which is equivalent to the set-up time for microprobing.

FIG. 2b illustrates an alternate configuration for single-die bond-out, which permits observation of the die from either the frontside or backside, without remounting the die. Device carrier 200 has hole 210 therethrough, and DUT 215 is mounted from its edges 220 so as to be suspended within hole 210, with both its frontside and backside exposed for observation. Suspension may be accomplished, by way of example, by pressure fitting 225 with vertical physical contacts 230, so as not to be in contact with or damage frontside or backside of DUT 215. Microbonds 235 can be formed between points on DUT 215 and bonding pads 240 on device carrier 200, as in the previously described case.

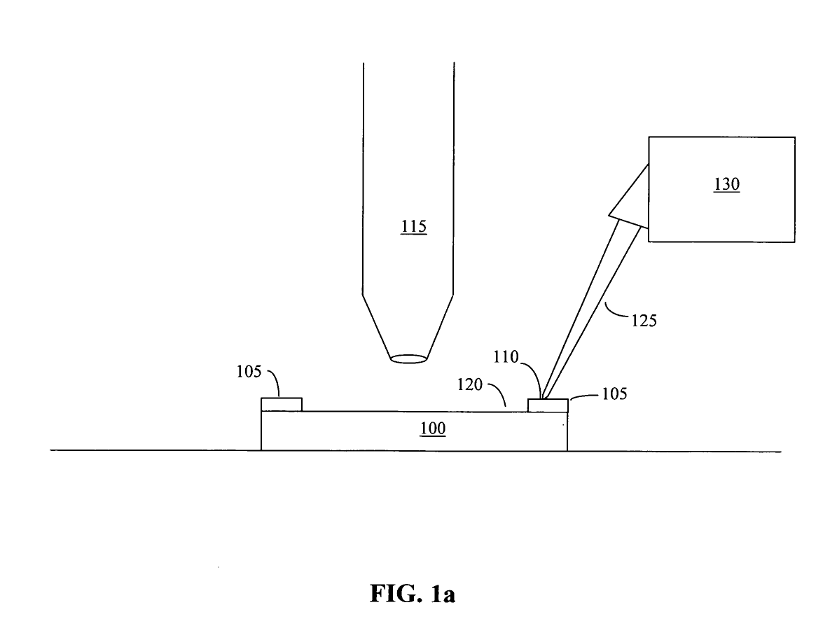

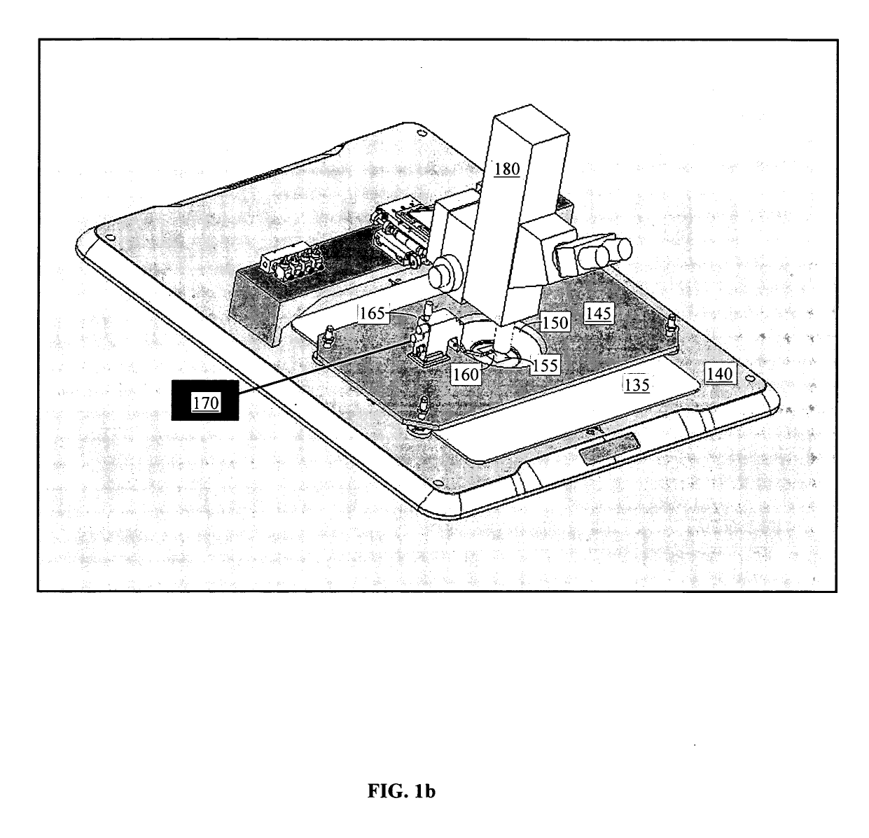

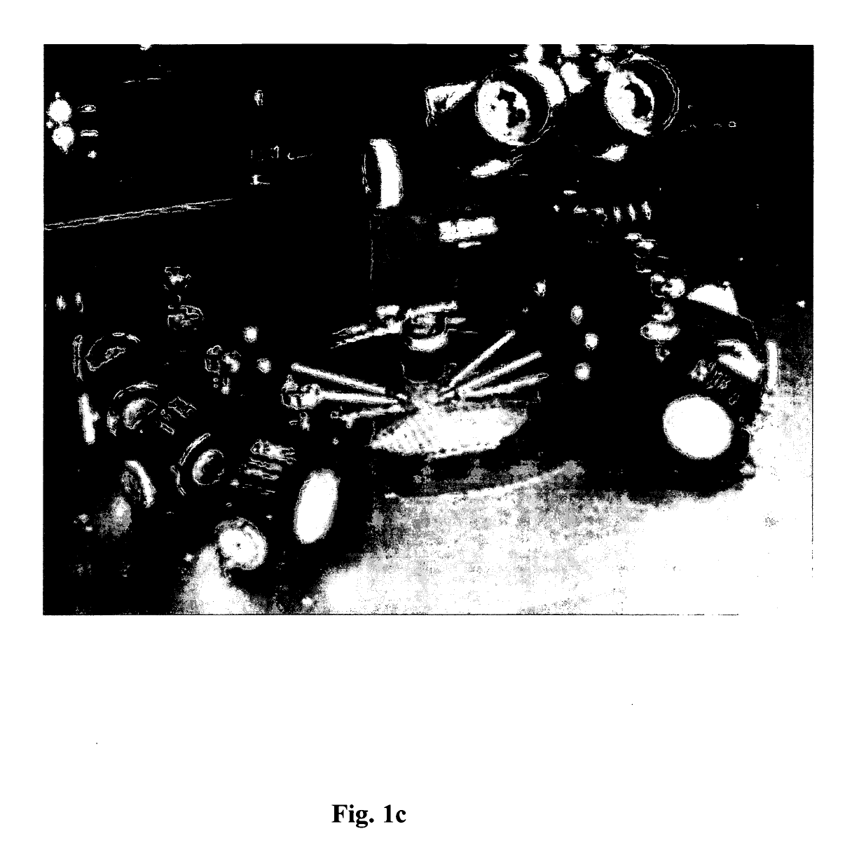

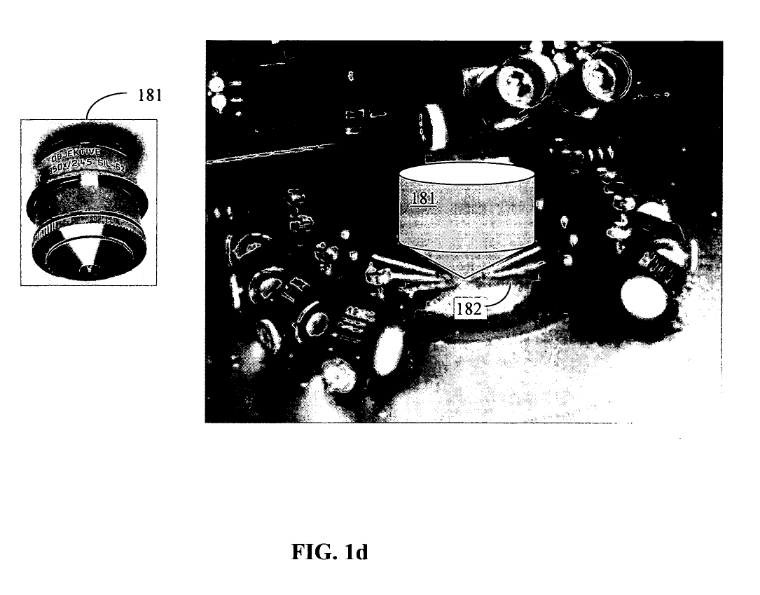

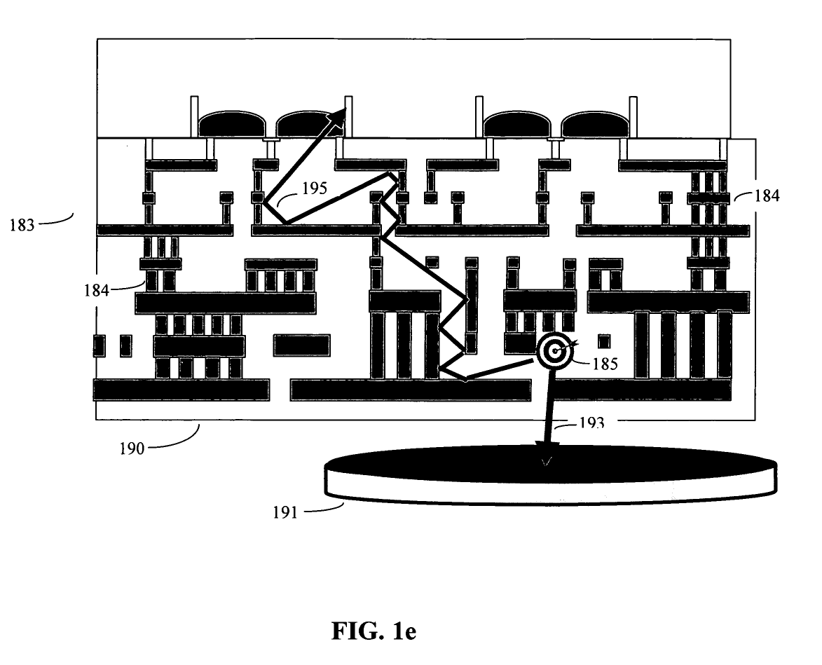

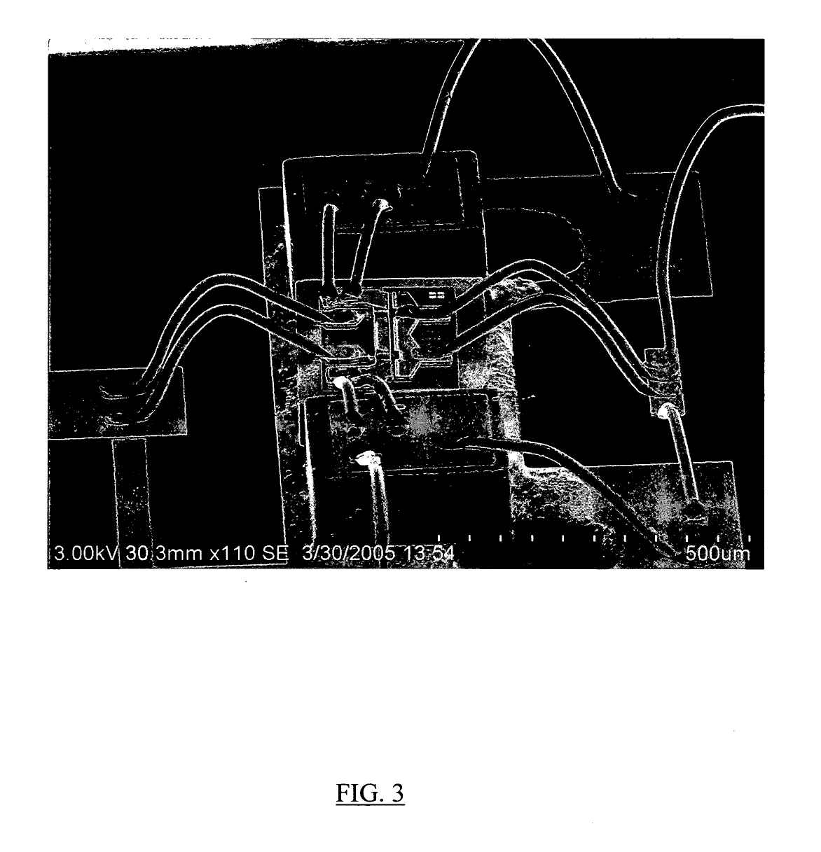

The bonding for both the cases illustrated in FIG. 2a and FIG. 2b may be, for example, wedge bonding as illustrated in FIG. 3. Wedge bonding, where the wire to be bonded approaches the bonding surface nearly horizontally, is the preferred bonding method. In contrast, the other possible bonding method, ball bonding, is less desirable (although still usable in some circumstances) since the bonding wire approaches the surface nearly vertically. This can result in interference of the bond wires with the nearby objective lens, particularly in the case of the ultra-high NA lens as illustrated in FIG. 1d. Many types of wire bonders may be used, for example the F&K Delvotec Model 5330 manual wire bonder. If necessary, bond wires may be removed by grasping each wire singly with tweezers and pulling each wire loose. A small bump of bond metal is left behind, but the DUT is otherwise unharmed by this process. The sample adhesive is then dissolved with acetone and the DUT is then separated from the carrier. Acetone is routinely used for sample cleaning in semiconductor labs and the DUT is unharmed by this process.

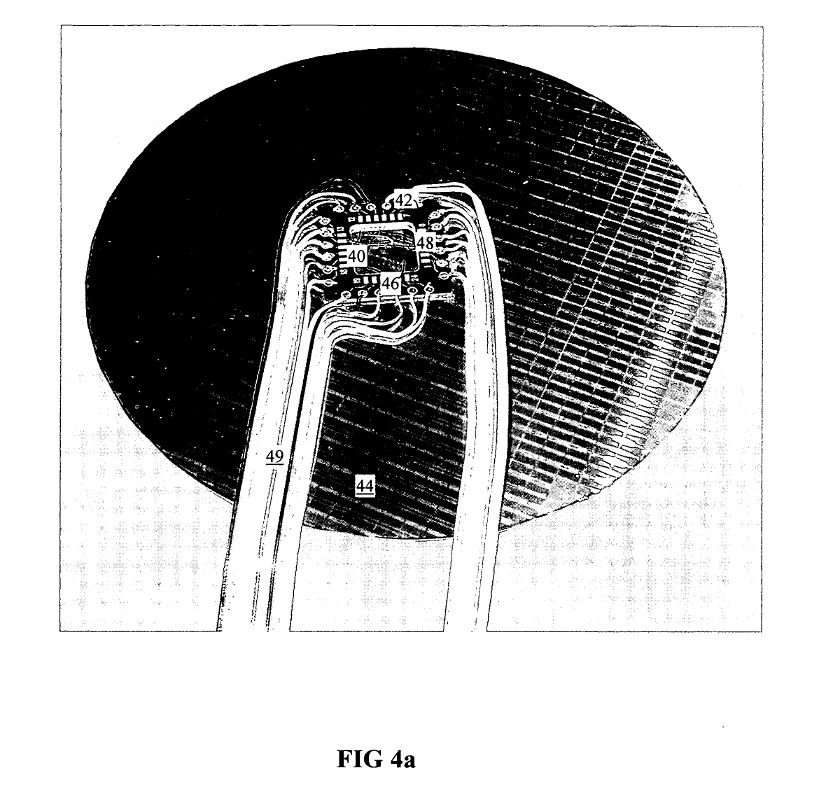

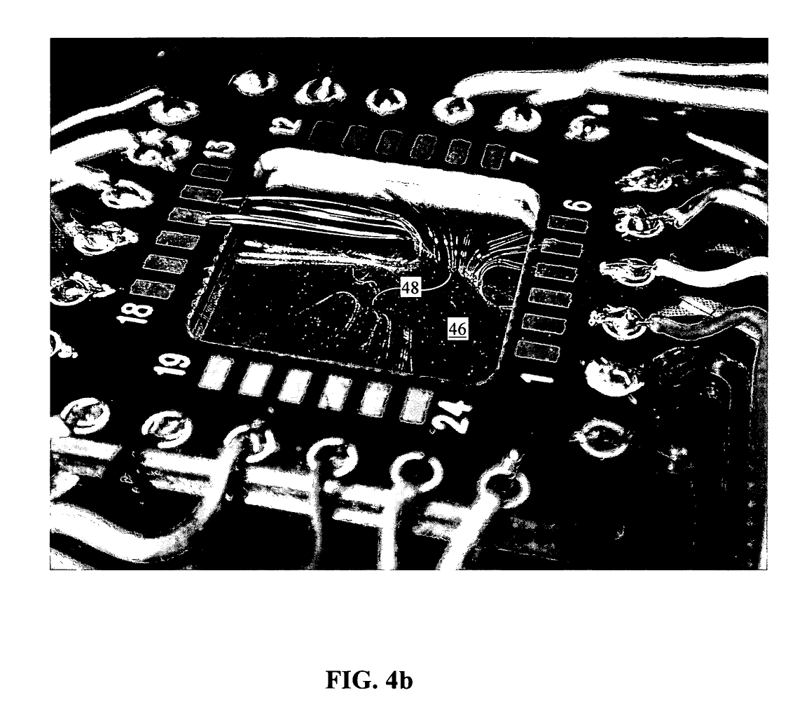

A configuration is disclosed herein and illustrated in FIG. 4a, wherein the direct bond-out method can be utilized for on-wafer chip diagnostics. Hole 40 is cut in device carrier 42, which may be a standardized PC board. Carrier 42 is glued to the front side of wafer 44, such that die 46 which is to be contacted or probed is exposed in the center of hole 40. The gluing and removal processes are similar to those described above for the single die case.

Once the PC board 42 is mounted on the frontside of the wafer 44 with the die 46 exposed, permanent micro-bonds 48 can be made from the die to the PC board, as is described above for the single-die case. Wires can then be extended from the PC board pads to the outside edge of the wafer Ribbon cables or flexible PCB can be connected to the carrier prior to its mounting to the wafer. Such flexible conductors can be terminated in a multitude of ways (including but not limited to: PCB connection, other card edge connections, IDC connectors, other pin and socket connectors, individual wire splices, etc.). FIG. 4b shows a close-up of the DUT 46 with a large number of micro-bonds 48, illustrating the usefulness of the inventive method in enabling a much larger number of electrical connections than would be possible using micro-probes.

In an alternative embodiment, the PC board can be elongated so as to extend beyond the edges of the wafer, in which case custom mother board connectors, including but not limited to coax or SMA, can be added directly to the PC board.

Using the configurations disclosed herein, bond-out schemes can be utilized either with single die or for on-wafer chip diagnostics. This allows for frontside photon emission observation with ultra-high NA objectives, and other applications such as TIVA, LIVA, OBIRCH. or other electrical or thermal responses to photon stimulation of the sample. The method provides secure, permanent, good electrical connections, and can be accomplished in about the same time required for setup of microprobes.

It is not intended that the invention be restricted to the exact embodiments disclosed herein. Modifications may be made without departing from the inventive concept. For example, other types of microbonding than wedge bonding may be used. Optical or thermal observation may be performed from the frontside or the backside of the wafer or DUT. The wafer bond-out configuration can be used with other types of measurements, for example electron beam probing of circuits. The scope of the invention should be construed in view of the claims.

With this in mind, we claim:

1. A method for configuring a semiconductor wafer having an integrated circuit die thereon so as to make an electrical connection to a first region of said integrated circuit die, said method comprising the steps of:
providing a device carrier having a hole therethrough, said hole being sufficiently large to completely encompass said first region on said integrated circuit die, said device carrier having a plurality of electrical contact regions thereon;
removably attaching said device carrier to the frontside of said wafer such that said first region of said integrated circuit die is completely exposed through said hole in said device carrier;
forming at least one permanent microbond, each said at least one permanent microbond being formed by bonding a first end of a microwire to a selected location in said first region on said integrated circuit die and bonding a second end of said microwire to one of said electrical contact regions on said device carrier;
such that electrical connection can be made to said selected location in said first region on said integrated circuit die via said electrical contact region on said device carrier.

2. The method of claim 1, wherein said electrical contact regions are bonding pads.

3. The method of claim 1, wherein said device carrier is a PC board.

4. The method of claim 1, wherein said step of removably attaching said device carrier to said frontside of said wafer comprises gluing said device carrier to the frontside of said wafer.

5. The method of claim 4, wherein said step of gluing said device carrier to the frontside of said wafer comprises utilizing a low-viscosity, cyanoacrylate-based adhesive.

6. The method of claim 1, wherein said step of bonding a first end of a microwire to a selected location in said first region on said integrated circuit die and bonding a second end of said microwire to one of said electrical contact regions on said device carrier comprise wedge bonding of said first and second ends of said microwire.

7. The method of claim 1, wherein said device carrier is a PC board and wherein said electrical contact regions on said device carrier are bonding pads.

8. The method of claim 7, further including the step of extending a wire from each of said one of said bonding pads to an outside edge of said wafer.

9. The method of claim 8, wherein said step of extending a wire from each of said one of said bonding pads to an outside edge of said wafer includes connecting to said device carrier prior to its attaching to said wafer, a flexible conductor selected from the group consisting of: ribbon cables and flexible PCB.

10. The method of claim 9, further including the step of terminating said flexible conductor with at least one connection.

11. The method of claim 10, wherein said at least one connection is chosen from the group consisting of: PCB connector, card edge connector, IDC connector, pin and socket connector, and individual wire splices.

12. The method of claim 7, wherein said PC board is elongated to extend beyond the edges of said wafer.

13. The method of claim 12, wherein custom mother board connectors are added directly to said PC board.

14. The method of claim 13, wherein said custom mother board connectors are chosen from the group consisting of: coax, SMA, PCB connector, card edge connector, IDC connector, and pin and socket connector.

15. A method of performing diagnostics on an integrated circuit die on a wafer comprising the steps of:
making at least one electrical connection to said die using the method of claim 1;
applying an electrical signal to said die through said electrical connection; and
observing output from said die resulting from said applied electrical signal.

16. The method of claim 15, wherein said output is optical output.

17. The method of claim 16, wherein said step of observing said optical output from said die comprises using an optical microscope.

18. The method of claim 17, wherein said optical microscope includes an ultrahigh NA objective lens.

19. The method of claim 16, wherein said optical output is photon emission.

20. The method of claim 15, wherein said output is thermal output.

21. The method of claim 15, wherein said output is observed from the frontside of the wafer.

22. The method of claim 15, wherein said output is observed from the backside of the wafer.

23. A method of performing diagnostics on an integrated circuit die on a wafer comprising the steps of:
making at least one electrical connection to said die using the method of claim 1;
providing optical excitation to said die; and
measuring electrical response to said optical excitation of said die via said at least one electrical connection.

24. The method of claim 23, wherein said step of providing optical excitation to said die comprises illuminating said die with coherent radiation from a laser source.

25. The method of claim 24, wherein said die is illuminated from the frontside of said wafer.

26. The method of claim 24, wherein said die is illuminated from the backside of said wafer.

27. The method of claim 23, wherein said step of measuring electrical response to said optical excitation of said die via said at least one electrical connection comprises TIVA measurements.

28. The method of claim 23, wherein said step of measuring electrical response to said optical excitation of said die via said at least one electrical connection comprises LIVA measurements.

29. The method of claim 23, wherein said step of measuring electrical response to said optical excitation of said die via said at least one electrical connection comprises OBIRCH measurements.

30. The method of claim 23, wherein said step of measuring electrical response to said optical excitation of said die via said at least one electrical connection comprises OBIC measurements.

31. The method of claim 23, wherein said step of measuring electrical response to said optical excitation of said die via said at least one electrical connection comprises a measurement method chosen from the group consisting of: LADA, SDL, RIL, and XIVA.

32. A method for configuring an integrated circuit die so as to make an electrical connection to a first region of said integrated circuit die, said method comprising the steps of:
providing a device carrier having a hole therethrough, said hole being sufficiently large to completely encompass integrated circuit die, said device carrier having a plurality of electrical contact regions thereon;
removably attaching said integrated circuit die within said hole through said device carrier such that said first region of said integrated circuit die is completely exposed through said hole in said device carrier;
forming at least one permanent microbond, each said at least one permanent microbond being formed by bonding a first end of a microwire to a selected location in said first region on said integrated circuit die and bonding a second end of said microwire to one of said electrical contact regions on said device carrier;
such that electrical connection can be made to said selected location in said first region on said integrated circuit die via said electrical contact region on said device carrier.

33. The method of claim 32, wherein said step of removably attaching said integrated circuit die within said hole through said device carrier such that said first region of said integrated circuit die is completely exposed through said hole in said device carrier comprises mounting said integrated circuit die to said device carrier from the edges of said integrated circuit die, the surface of said integrated circuit die being parallel to the surface of said device carrier;
such that said integrated circuit die can be observed from both its frontside and its backside.

34. The method of claim 33, wherein said step of mounting said integrated circuit die to said device carrier from the edges of said integrated circuit die utilizes a pressure fitting with vertical physical contacts.
